(19) United States
(12) Patent Application Publication
(10) Pub. No.: US 2024/0268192 A1
(43) Pub. Date: Aug. 8, 2024

(54) DISPLAY DEVICE

(71) Applicant: SAMSUNG DISPLAY CO., LTD., YONGIN-SI (KR)

(72) Inventors: JAEHEUNG HA, Yongin-si (KR); SU JEONG KIM, Yongin-si (KR); DUCKJONG SUH, Yongin-si (KR)

(21) Appl. No.: 18/430,024

(22) Filed: Feb. 1, 2024

(30) Foreign Application Priority Data
Feb. 2, 2023 (KR) 10-2023-0013986

(51) Int. Cl. H10K 59/80; G02B 27/01; H10K 59/38

(52) U.S. Cl. CPC H10K 59/873; G02B 27/017; H10K 59/38; H10K 59/879; G02B 2027/0178

(57) ABSTRACT

A display device includes a substrate, a plurality of pixels, and an encapsulation layer. The encapsulation layer is disposed on the pixels. The encapsulation layer has a multi-layer structure or a single-layer structure. When a distance (d) between the pixels and a thickness (t) of the encapsulation layer satisfies Mathematical Formula 1: t≤ (d/tan 10°), color mixing is prevented in the display device.

### CROSS-REFERENCE TO RELATED APPLICATION

This application claims priority under 35 U.S.C. § 119 to Korean Patent Application No. 10-2023-0013986, filed on Feb. 2, 2023, the content of which in its entirety is herein incorporated by reference.

### TECHNICAL FIELD

The disclosure relates to a display device. More specifically, the disclosure relates to a microdisplay device.

### DISCUSSION OF THE RELATED ART

A display device is a device that displays an image to provide visual information to a user. The display device may be a flat panel display device. For example, the flat panel display may be a liquid crystal display, a field emission display, a light emitting display, or the like. The display device may include a light-emitting diode. The light-emitting diode may include an organic light-emitting diode, an inorganic semiconductor diode, a subminiature light-emitting diode (or a micro light-emitting diode), or the like. That is, the display device may include an organic light-emitting display device, an inorganic light-emitting display device, a subminiature light-emitting display device (or a micro display device), or the like.

Recently, a head-mounted display including the light-emitting display device has been developed. Head Mounted Display (HMD) may be a virtual reality (VR) device or augmented reality (AR) device that is worn by a user in the form of glasses or a helmet and that forms a focus at a distance close to the eyes. The HMD may provide an image displayed on the display device to the user's eyes through a lens.

When a light-emitting diode including an organic material is exposed to moisture or oxygen, the quality of the display device may deteriorate. To prevent this, the display device may include an encapsulation layer to protect the light-emitting diode. For example, the light-emitting layer including the light-emitting diode may be located between a substrate and a cover window. The encapsulation layer may be located between the light-emitting layer and the cover window.

### SUMMARY

The disclosure may provide a display device in which color mixing is prevented.

A display device according to an embodiment includes a substrate, a plurality of pixels disposed on the substrate, and an encapsulation layer disposed on the plurality of pixels and having a single-layer structure. A distance (d) between the plurality of pixels and a thickness (t) of the encapsulation layer are configured to satisfy the relation of t≤ (d/tan 10°).

In an embodiment, the substrate may include a silicon substrate.

In an embodiment, each of the plurality of pixels may include a first electrode on the substrate, a light emitting element disposed on the first electrode, and a second electrode disposed on the light emitting element.

In an embodiment, the light emitting element may include a plurality of light emitting layers.

In an embodiment, the light emitting element may be configured to emit a whit light. In an embodiment, the display device may further include a color filter layer disposed on the encapsulation layer.

In an embodiment, the display device may further include a plurality of lenses disposed on the second electrode.

In an embodiment, each of the plurality of pixels may include sub-pixels, and the plurality of lenses may overlap the plurality of sub-pixels, respectively.

In an embodiment, the first electrode may be an anode, and the second electrode may be a cathode.

In an embodiment, the distance (d) may have a value of a micrometer scale or less.

A display device according to an embodiment includes a substrate, a plurality of pixels disposed on the substrate, and an encapsulation layer disposed on the plurality of pixels and having a multi-layer structure. A distance (d) between the plurality of pixels and a thickness (t) of the encapsulation layer are configured to satisfy the relation of t≤ (d/tan 10°).

In an embodiment, the substrate may include a silicon substrate.

In an embodiment, each of the plurality of pixels may include a first electrode on the substrate, a light emitting element disposed on the first electrode, and a second electrode disposed on the light emitting element.

In an embodiment, the light emitting element may include a plurality of light emitting layers.

In an embodiment, the light emitting element may be configured to emit a whit light. In an embodiment, the display device may further include a color filter layer disposed on the encapsulation layer.

In an embodiment, the display device may further include a plurality of lenses disposed on the second electrode.

In an embodiment, each of the plurality of pixels may include a plurality of sub-pixels, and the plurality of lenses may overlap the plurality of sub-pixels, respectively.

In an embodiment, the first electrode may be an anode, and the second electrode may be a cathode.

In an embodiment, the distance (d) may have a value of a micrometer scale or less.

A display device according to an embodiment may include a substrate, a plurality of pixels disposed on the substrate and spaced apart from each other at a first distance (d1), wherein each of the plurality of pixels includes a plurality of sub-pixels that are spaced apart from each other at a second distance (d2), and an encapsulation layer disposed on the plurality of pixels and having a thickness (t). The thickness (t) and a smaller distance (d) of the first distance (d1) and the second distance (d2) satisfy the relation of t≤ (d/tan 10°).

In an embodiment, the substrate may include a silicon substrate.

In an embodiment, each of the plurality of pixels may include a first electrode on the substrate, a light emitting element disposed on the first electrode, and a second electrode disposed on the light emitting element.

In an embodiment, the display device may further include a plurality of lenses disposed on the second electrode.

In an embodiment, each of the plurality of pixels may include sub-pixels, and the plurality of lenses may overlap the plurality of sub-pixels, respectively.

In an embodiment, the distance (d) may have a value of a micrometer scale or less.

A display device according to the embodiments may include a substrate, a plurality of pixels, and an encapsulation layer. The encapsulation layer may be disposed on the pixels. The encapsulation layer may have a multi-layer (or a single-layer) structure. When a distance (d) between the pixels and a thickness (t) of the encapsulation layer satisfies the relation of t≤ (d/tan 10°), color mixing may be prevented in the display device.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a plan view illustrating a display device according to embodiments of the disclosure.

FIG. 2 is a view illustrating pixels included in the display device of FIG. 1.

FIG. 3 is a cross-sectional view taken along a line I-I of FIG. 2.

FIG. 4 is an enlarged view of a region A of FIG. 3.

FIG. 5 is a view illustrating an element wiring layer according to an embodiment included in the display device of FIG. 4.

FIG. 6 is a view illustrating an element wiring layer according to an embodiment included in the display device of FIG. 4.

FIGS. 7 to 12 are views illustrating a method of manufacturing a display device according to embodiments of the disclosure.

FIG. 13 is view illustrating an embodiment in which the display device of FIG. 1 is implemented as smart glasses.

FIG. 14 is a view illustrating an embodiment in which the display device of FIG. 1 is implemented as a head mounted display device.

### DETAILED DESCRIPTION

Embodiments of the present disclosure will be more clearly understood from the following detailed description in conjunction with the accompanying drawings.

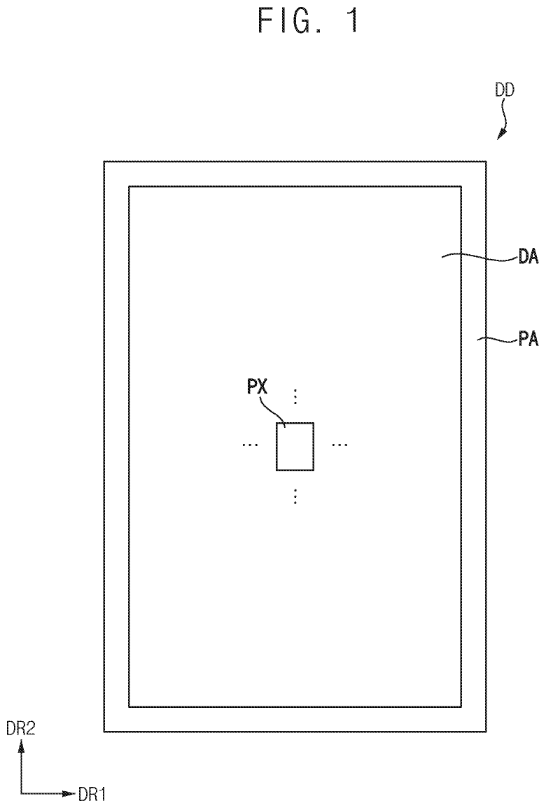

FIG. 1 is a plan view illustrating a display device according to embodiments of the DISCLOSURE

Referring to FIG. 1, according to embodiments of the disclosure, a display device DD may include a display region DA and a non-display region PA.

The display region DA may be an area that displays an image. For example, a planar shape of the display region DA may be a rectangle with rounded corners. However, the disclosure is not limited thereto. For example, the display region DA may have various planar shapes such as a circular shape, an elliptical shape, and a polygonal shape.

The non-display region PA may be an area that is not displayed the image. For example, a driving unit for displaying the image of the display region DA may be disposed in the non-display region PA. The non-display region PA may be disposed around the display region DA. For example, the non-display region PA may surround the display region DA. Specifically, the non-display region PA may entirely surround the display region DA. Alternatively, the non-display region PA may be disposed on only a side of the display region DA.

A plurality of pixels PX may be disposed in the display region DA. For example, the plurality of pixels PX may be disposed in the display region DA in a matrix form. Specifically, the pixels PX may be repeatedly arranged in a first direction DR1 and a second direction DR2 in a plan view. The second direction DR2 may cross the first direction DR1. For example, the second direction DR2 may be perpendicular to the first direction DR1. Each of the pixels PX may be defined as a minimum light emitting unit capable of displaying light of various colors. For example, the plurality of pixels may be defined as the minimum light emitting unit capable of displaying a white light.

A plurality of signal lines may be disposed in the display region DA. For example, scan lines, data lines, or the like may be disposed in the display region DA. For example, the scan lines may extend in the second direction DR2 and may be arranged in the first direction DR1. The data lines may extend in the first direction DR1 and may be arranged in the second direction DR2.

The signal lines may be connected to the pixels PX, respectively. Accordingly, each of the pixels PX may receive signals from the signal lines. For example, each of the pixels PX may receive a scan signal from the scan line and may receive a data signal from the data line. Accordingly, the display device DD may display the image in a third direction crossing each of the first direction DR1 and the second direction DR2. For example, the first and second directions DR1 and DR2 may be parallel to an upper surface of the display region DA, and the third direction may be perpendicular to the upper surface of the display region DA.

The display device DD may have various planar shapes on a plane. For example, the display device DD may have a rectangle with rounded corners on the plane. In this case, the plane may be defined by the first direction DR1 and the second direction DR2. For example, the display device DD may have a rectangular shape having a long side in the first direction DR1 and a short side in the second direction DR2.

The display device DD may include light emitting elements having various sizes. For example, the display device DD may be a microdisplay. The microdisplay may include a subminiature light emitting diode (or a micro-light emitting diode).

For example, the display device DD may be a self-luminous (emissive) microdisplay. The self-luminous microdisplay may generate a light by itself so that the self-luminous microdisplay may not include a separate light source. However, the present disclosure is not limited thereto.

As another example, the display device DD may be a reflective microdisplay. The reflective microdisplay may include a light source located on a front side of a panel of the microdisplay. The reflective microdisplay may employ a scheme of modulating an external light while varying characteristics (a refractive index, a transmittance, etc.) of a reflective surface to reflect and view an image.

As still another example, the display device DD may be a transmissive microdisplay. The transmissive microdisplay may include a light source located on a rear side of a panel of the microdisplay. The transmissive microdisplay may have the same structure as a liquid crystal display (LCD).

However, the disclosure is not limited thereto. The display device DD may include light emitting elements having various sizes.

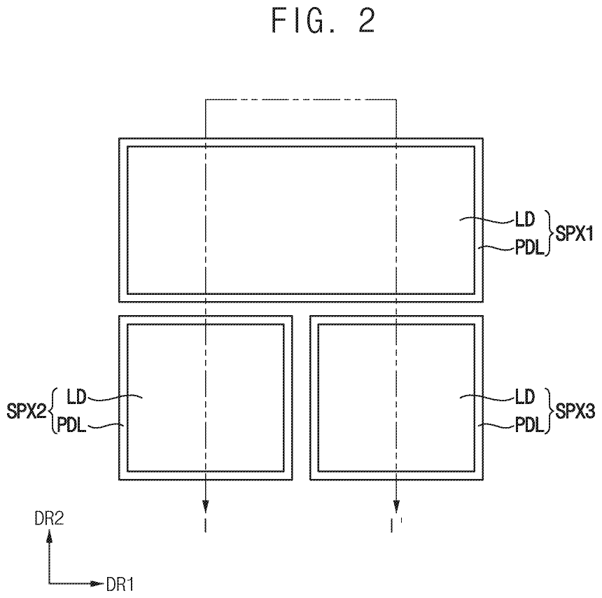

FIG. 2 is a view illustrating pixels included in the display device of FIG. 1.

Referring to FIGS. 1 and 2, each of the pixels PX may include a first sub-pixel region SPX1, a second sub-pixel region SPX2, and a third sub-pixel region SPX3.

Although each of the pixels PX has been shown in FIG. 2 as including the first sub-pixel region SPX1, the second sub-pixel region SPX2, and the third sub-pixel region SPX3, the present disclosure is not limited thereto. For example, each of the pixels PX may include at least four sub-pixel regions.

A light emitting element LD may be disposed in each of the first, second, and third sub-pixel regions SPX1, SPX2, and SPX3. In an embodiment, the light emitting element LD may emit a first light. For example, the light emitting element LD may emit the white light. In another embodiment, the light emitting elements LD may emit lights having mutually different colors. For example, each of the light emitting elements LD may emit a light having one color among a red color, a blue color, and a green color. However, the disclosure is not limited thereto. For example, each of the light emitting elements LD may emit a light having one color among a yellow color, a cyan color, and a magenta color.

The light emitting element LD may have various planar shapes. In an embodiment, the light emitting element LD may have a polygonal shape on the plane. For example, the light emitting element LD may have a quadrangular shape on the plane. However, the disclosure is not limited thereto. For example, the light emitting element LD may have various shapes such as a circular shape, an elliptical shape, and a polygonal shape other than a quadrangular shape.

The light emitting element LD in the first sub-pixel region SPX1 may emit a second light. The first sub-pixel region SPX1 may convert the first light emitted from the light emitting element LD to the second light and emit the second light. For example, the second light may be a blue light. However, the disclosure is not limited thereto.

The light emitting element LD in the second sub-pixel region SPX2 may emit a third light. The second sub-pixel region SPX2 may convert the first light emitted from the light emitting element LD to the third light and emit the third light. For example, the third light may be a red light. However, the disclosure is not limited thereto.

The light emitting element LD in the third sub-pixel region SPX3 may emit a fourth light. The third sub-pixel region SPX3 may convert the first light emitted from the light emitting element LD to the fourth light and emit the fourth light. For example, the fourth light may be a green light. However, the disclosure is not limited thereto.

The lights emitted from the first sub-pixel region SPX1, the second sub-pixel region SPX2, and the third sub-pixel region SPX3 may be combined to emit lights having various colors.

In an embodiment, the first sub-pixel region SPX1, the second sub-pixel region SPX2, and the third sub-pixel region SPX3 may have mutually different areas in the plan view. For example, when the blue light is emitted from the first sub-pixel region SPX1, an area of the first sub-pixel region SPX1 may be larger than an area of the second sub-pixel region SPX2. In addition, the area of the first sub-pixel region SPX1 may be larger than an area of the third sub-pixel region SPX3. In another embodiment, each of the sub-pixel regions SPX1, SPX2, and SPX3 may have substantially the same area in the plan view.

The first sub-pixel region SPX1, the second sub-pixel region SPX2, and the third sub-pixel region SPX3 may have various arrangements in the plan view. For example, the first sub-pixel region SPX1 may be arranged in a row that is different from a row in which the second sub-pixel region SPX2 is arranged. In addition, the first sub-pixel region SPX1 may be positioned in a row that is different from a row in which the third sub-pixel region SPX3 is positioned. The second sub-pixel region SPX2 and the third sub-pixel region SPX3 may be positioned in the same row. However, the disclosure is not limited thereto.

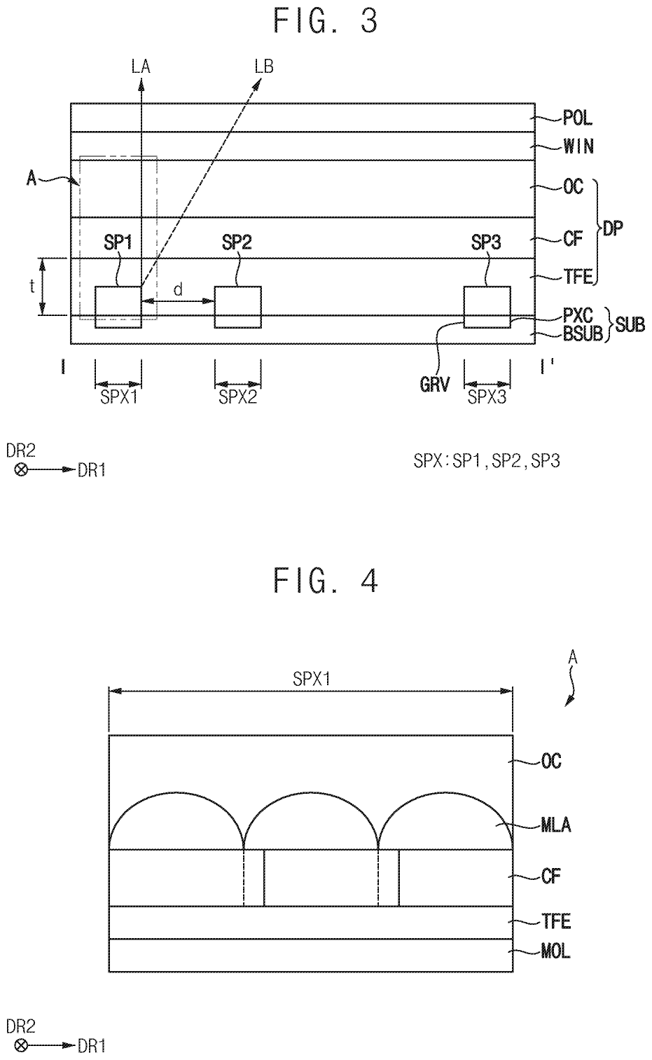

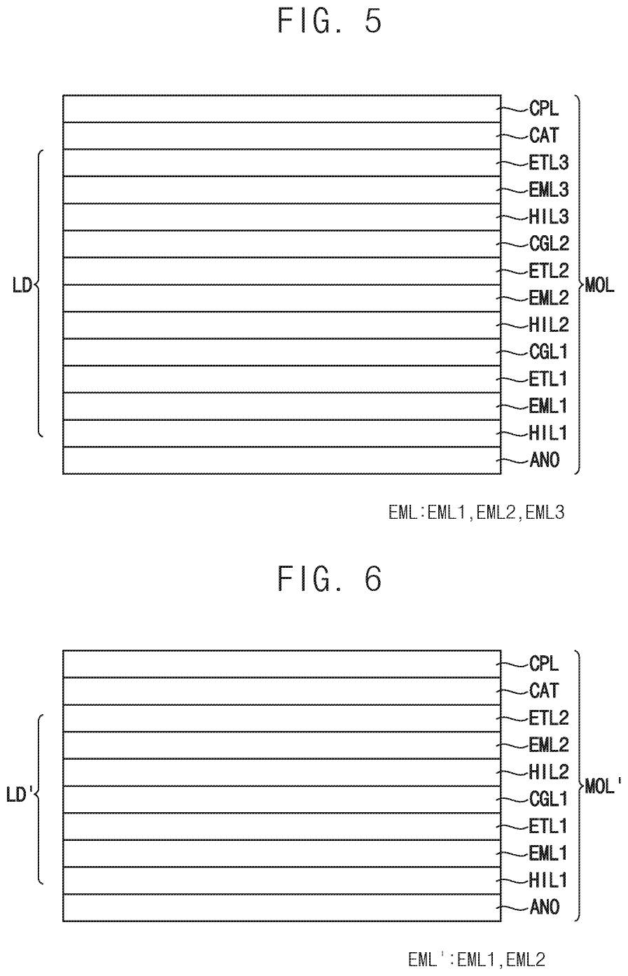

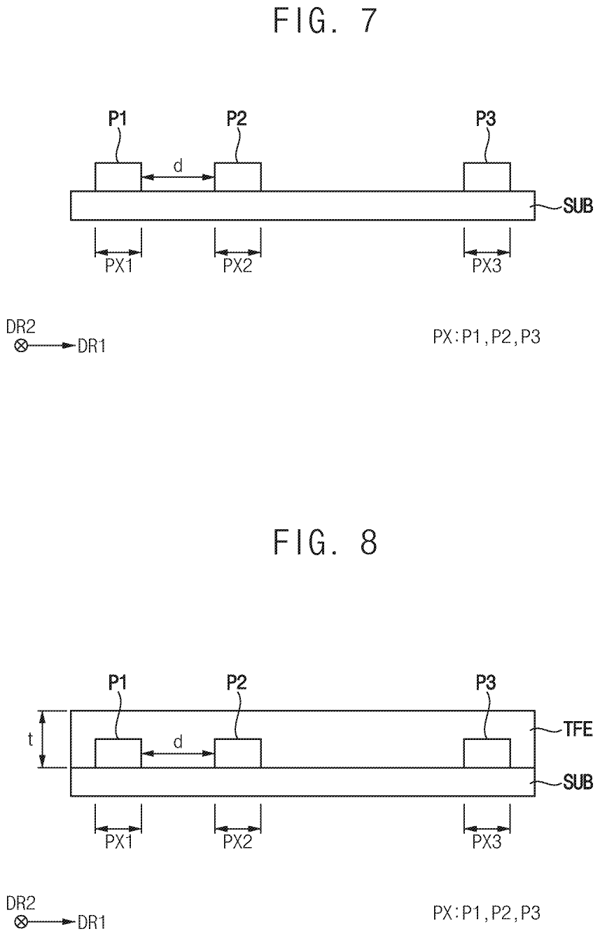

FIG. 3 is a cross-sectional view taken along a line I-I of FIG. 2. FIG. 4 is an enlarged view of a region A of FIG. 3. FIG. 5 is a view illustrating an element wiring layer according to an embodiment included in the display device of FIG. 4.

For example, FIG. 4 is an enlarged view illustrating the first sub-pixel region SPX1 of FIG. 3. Components disposed in each of the second and third sub-pixel regions SPX2 and SPX3 may be substantially identical to components disposed in the first sub-pixel region SPX1. For convenience of description, descriptions will focus on the first sub-pixel region SPX1 below.

Referring to FIGS. 1, 2, 3, and 4, the display device DD according to an embodiment may include a substrate SUB, an element wiring layer MOL, an encapsulation layer TFE, a color filter layer CF, an overcoat layer OC, a cover window WIN, and a polarizing layer POL.

When the display device DD is the microdisplay, the substrate SUB may be a silicon wafer (i.e., a silicon substrate). In some embodiments, the substrate SUB may be a semiconductor circuit board. The substrate SUB may include a base substrate BSUB and a plurality of pixel circuit parts PXC.

The base substrate BSUB may include the silicon wafer. A plurality of grooves GRV may be defined in the base substrate BSUB. For example, the plurality of grooves GRV may be formed at an upper surface of the base substrate BSUB. Each of the plurality of pixel circuit parts PXC may be accommodated in a corresponding groove of the plurality of grooves GRV.

The plurality of pixel circuit parts PXC may be disposed on the base substrate BSUB. Each of the plurality of pixel circuit parts PXC may include at least a transistor. In addition, each of the plurality of pixel circuit parts PXC may further include at least a capacitor.

However, the disclosure is not limited thereto. For example, the substrate SUB may include various materials. For example, the substrate SUB may include various materials such as glass and plastic. These may be used alone or in combination with each other.

A display part DP may be disposed on the substrate SUB. The display part DP may include the element wiring layer MOL, the encapsulation layer TFE, the color filter layer CF, and the overcoat layer OC.

The element wiring layer MOL may be disposed on the substrate SUB. The plurality of sub-pixels SPX may be disposed on the element wiring layer MOL. Specifically, the element wiring layer MOL may include an insulating layer and the light emitting element LD. More specifically, the element wiring layer MOL may include the insulating layer, a first electrode ANO, the light emitting element LD, a second electrode CAT, and a capping layer CPL.

The insulating layer may be disposed between the substrate SUB and the element wiring layer MOL. The insulating layer may include first openings exposing the plurality of pixels PX.

The insulating layer may be disposed between the substrate SUB and the device wiring layer MOL. The insulating layer may include second openings exposing the plurality of pixel circuit parts PXC.

The first electrode ANO may be disposed on the substrate SUB. For example, the first electrode ANO may be disposed on the insulating layer.

The first electrode ANO may include or may be formed of a conductive material. For example, the first electrode ANO may include or may be formed of a metal, an alloy, a conductive metal oxide, a transparent conductive material, or the like. More specifically, the first electrode ANO may include or may be formed of ITO, IZO, ZnO, In₂O₃, or the like. These may be used alone or in combination with each other.

In an embodiment, the first electrode ANO may be an anode. For example, the first electrode ANO may be electrically connected to the plurality of pixel circuit parts PXC. Specifically, the first electrode ANO may be disposed within a corresponding opening of the first openings defined in the insulating layer, and the first electrode ANO may be electrically connected to the plurality of pixel circuit parts PXC.

The first electrode ANO may receive a driving current provided from the transistor. As described above, the transistor may be included in the plurality of pixel circuit parts PXC. For example, the first electrode ANO may receive an anode voltage from the transistor.

However, the disclosure is not limited thereto. The first electrode ANO may also be a cathode.

In an embodiment, the light emitting element LD may be disposed on the first electrode ANO. For example, the light emitting element LD may be disposed on the first electrode ANO and the insulating layer.

The light emitting element LD may include a light emitting layer EML and a functional layer.

The light emitting layer EML may include an organic material that emits light of a predetermined color.

The functional layer may assist light emission of the light emitting layer EML. Examples of the functional layer may include a hole transport layer, a hole injection layer, an electron transport layer, an electron injection layer, or the like.

In an embodiment, the light emitting element LD may have a tandem structure. For example, the light emitting element LD may include a plurality of light emitting layers EML1, EML2, and EML3. Specifically, the light emitting element LD may include a first hole injection layer HIL1, a first light emitting layer EML1, a first electron transport layer ETL1, a first charge generation layer CGL1, a second hole injection layer HIL2, a second light emitting layer EML2, a second electron transport layer ETL2, a second charge generation layer CGL2, a third hole injection layer HIL3, a third light emitting layer EML3, and a third electron transport layer ETL3 sequentially stacked on the substrate SUB.

White light may be emitted from the light emitting element LD by combining light emitted from the plurality of light emitting layers EML1, EML2, and EML3.

However, the disclosure is not limited thereto. A stacking order of the functional layers or a type of the stacked layer may be changed. Alternatively, the functional layer may be omitted.

In an embodiment, the second electrode CAT may be disposed on the light emitting element LD. For example, the second electrode CAT may extend along the first sub-pixel area SPX1, the second sub-pixel area SPX2, and the third sub-pixel area SPX3. That is, the second electrode CAT may be integrally formed along the first sub-pixel area SPX1, the second sub-pixel area SPX2, and the third sub-pixel area SPX3. However, the disclosure is not limited thereto. The second electrode CAT may be separately formed in each of the first sub-pixel area SPX1, the second sub-pixel area SPX2, and the third sub-pixel area SPX3.

The second electrode CAT may include or may be formed of a conductive material. For example, the second electrode CAT may include or may be formed of a metal, an alloy, a conductive metal oxide, a transparent conductive material, or the like. More specifically, the second electrode CAT may include or may be formed of Li, Ca, LiF/Ca, LiF/Al, Al, Ag, Mg, Ba, or the like. These may be used alone or in combination with each other.

In an embodiment, the second electrode CAT may be the cathode. Light may be emitted from the light emitting layer EML by a voltage difference between the first electrode ANO and the second electrode CAT.

However, the disclosure is not limited thereto. The second electrode CAT may be the anode.

In an embodiment, the capping layer CPL may be disposed on the second electrode CAT. The capping layer CPL may protect the second electrode CAT. In another embodiment, the capping layer CPL may be omitted.

The encapsulation layer TFE may be disposed on the substrate SUB and the plurality of sub-pixels SPX. Specifically, the encapsulation layer TFE may be disposed on the element wiring layer MOL. More specifically, the encapsulation layer TFE may be disposed on the second electrode CAT.

The encapsulation layer TFE may cover the plurality of sub-pixels SPX.

Accordingly, the encapsulation layer TFE may prevent penetration of moisture or oxygen into the light emitting element LD.

In an embodiment, the encapsulation layer TFE may have or may be a single-layer structure.

For example, the encapsulation layer TFE may be an inorganic film having the single-layer structure. The encapsulation layer TFE may include or may be formed of the inorganic film, such as silicon oxide (SiO₂), silicon nitride (SiNx), and silicon oxynitride (SiON), that may have high mechanical strength.

For another example, the encapsulation layer TFE may be an organic film having the single-layer structure. For example, the organic layer may include acrylate. An upper surface of the encapsulation layer TFE including the organic film may be flat.

In another embodiment, the encapsulation layer TFE may have a multi-layer structure.

For example, the encapsulation layer TFE may include at least an inorganic layer and at least an organic layer. For example, the encapsulation layer TFE may include a first inorganic layer, an organic layer, and a second inorganic layer. The first inorganic layer may be disposed on the element wiring layer MOL. The organic layer may be disposed on the first inorganic layer. The second inorganic layer may be disposed on the organic layer. For example, the organic layer may be disposed between the first inorganic layer and the second inorganic layer. When the encapsulation layer TFE has the multi-layer structure, sealing property (e.g., a property of protecting the light emitting element LD from external moisture and oxygen) may be increased. In addition, since the encapsulation layer TFE includes the organic layer, the upper surface of the encapsulation layer TFE may be flat.

In an embodiment, the sub-pixels SPX may be arranged to have a predetermined distance d, and the encapsulation layer TFE may have a predetermined thickness t.

The predetermined distance d may represent the smallest value among a distance between the pixels PX and a distance between the sub-pixels SPX. For example, in a case that the distance between the pixels PX is smaller than the distance between the sub-pixels SPX, the predetermined distance d may correspond to the distance between the pixels PX. Otherwise, the predetermined distance d may correspond to the distance between the sub-pixels SPX. Although the predetermined distance d will be described below as a minimum distance between the sub-pixels SPX, the disclosure is not limited thereto. For example, when each of the pixels PX includes only one sub-pixel, the predetermined distance d may be a distance between the pixels PX. On the other hand, as shown in FIG. 2, a first distance between the first sub-pixel region SPX1 and the second sub-pixel region SPX2, a second distance between the second sub-pixel region SPX2 and the third sub-pixel region SPX3, and a third distance between the third sub-pixel region SPX3 and the first sub-pixel region SPX1 may be different from each other. In this case, the predetermined distance d may represent the smallest value among the first distance, the second distance, and the third distance.

In addition, the predetermined thickness t may represent the maximum thickness of the encapsulation layer TFE at the predetermined distance d.

In an embodiment, the encapsulation layer TFE may have the single-layer structure. In this case, the predetermined thickness t may represent the thickness of the single-layer. In other words, the predetermined thickness t may represent a thickness of the thickest portion of the single layer.

In another embodiment, the encapsulation layer TFE may have the multi-layer structure. In this case, the predetermined thickness t may represent a sum of thicknesses of a plurality of layers. In other words, the predetermined thickness t may represent the largest value among sums of the thicknesses of the layers.

The encapsulation layer TFE may have a varying thickness varying according to positions of an intervening element such as a wire disposed on the element wiring layer MOL. For example, a first thickness of a first position at which the intervening element is disposed between the encapsulation layer TFE and the element wiring layer MOL may be different from a second thickness of a second position at which the intervening element is not disposed therebetween. The first thickness may be greater than the second thickness. In this case, the predetermined thickness t may represent the first thickness.

However, the disclosure is not limited thereto. The encapsulation layer TFE may be formed to have substantially the same thickness.

In an embodiment, a relation between the distance d between the sub-pixels SPX and the thickness t of the encapsulation layer TFE may satisfy Mathematical Formula 1 below.

$$t \leq \frac{d}{tan 10 °} \qquad 〈 Mathematical Formula 1 〉$$

The thickness t of the encapsulation layer TFE may be affected by the distance d between the sub-pixels SPX. For example, as the distance d between the sub-pixels SPX decreases, the thickness t of the encapsulation layer TFE may also be gradually decreased. For example, as the distance d between the sub-pixels SPX increases, the thickness t of the encapsulation layer TFE may also be gradually increased. Since the distance d between the sub-pixels SPX and the thickness t of the encapsulation layer TFE satisfy Mathematical Formula 1, color mixing between adjacent sub-pixels SPX may be prevented in the display device DD.

According to a display device of a comparative embodiment, the distance d between the plurality of sub-pixels SPX and the thickness t of an encapsulation layer TFE may not satisfy Mathematical Formula 1 as described above. For example, the thickness t of the encapsulation layer TFE included in the display device according to the comparative embodiment may be a thickness that is greater than a value obtained by dividing the distance d between the sub-pixels SPX by about tan 10°.

In this case, the light emitted from the first sub-pixel region SPX1 may pass through the color filter located on the second sub-pixel region SPX2 that is adjacent to the first sub-pixel region SPX1. Accordingly, a second sub-pixel SP2 may also emit the light emitted from the first sub-pixel region SPX1. As a first sub-pixel SP1 and the second sub-pixel SP2 emit lights together, the blue light and the green light may be emitted together, and an image formed by the color light in which the blue light and the green light are mixed may be displayed. For example, the first sub-pixel SP1 may emit the light from the second sub-pixel SP2 in addition to a first target amount of light for the first sub-pixel SP1, and the second sub-pixel SP2 may emit the light from the first sub-pixel SP1 in addition to a second target amount of light for the second sub-pixel SP2. In other words, the color mixing may occur in the display device according to the comparative embodiment.

On the other hand, according to the display device DD of the embodiments of the disclosure, the distance d between the sub-pixels SPX and the thickness t of the encapsulation layer TFE may satisfy Mathematical Formula 1 as described above.

For example, the thickness t of the encapsulation layer TFE included in the display device DD according to the embodiments of the disclosure may be a thickness that is less than a value obtained by dividing the distance d between the sub-pixels SPX by about tan 10°.

Alternatively, the thickness t of the encapsulation layer TFE included in the display device DD according to the embodiments of the disclosure may be a thickness that is equal to the value obtained by dividing the distance d between the sub-pixels SPX by about tan 10°.

In this case, a light emitted from the first sub-pixel region SPX1 might not pass through the color filter located on the second sub-pixel region SPX2 that is adjacent to the first sub-pixel region SPX1. For example, among lights emitted from the first sub-pixel SP1, only a light in which an angle formed between the light and a normal line of the substrate SUB is within an absolute value of about 10° may be recognized by a user, and a light in which the angle formed between the light and the normal line of the substrate SUB exceeds the absolute value of about 10° may be cut by the color filter layer CF so as not to be recognized by the user. In other words, only the first sub-pixel SP1 may emit the light, and only the image formed by the blue light may be displayed. For example, the light coming from the first sub-pixel SP1 may be prevented from entering other sub-pixels, and thus the color mixing may be prevented in the display device DD according to the embodiments of the disclosure.

In an embodiment, the display device DD may be the microdisplay. In this case, each of the sub-pixels SPX may have a size of about 4 μm to about 20 μm. Accordingly, the distance d between the sub-pixels SPX may also be on a micrometer scale. For example, when the distance d between the sub-pixels SPX is about 0.6 μm, the thickness t of the encapsulation layer TFE may be less than or equal to about 3.4 μm. In this case, the thickness t of the encapsulation layer TFE may be the thickness that is less than the value obtained by dividing the distance d between the sub-pixels SPX by about tan 10°, so that the color mixing may be prevented in the display device DD.

In an embodiment, the color filter layer CF may be disposed on the encapsulation layer TFE. In this case, the light emitting element LD may be a white organic light emitting element emitting white light. The white light emitted from the light emitting element LD may be converted into the light of various colors by passing through the color filter layer CF.

In another embodiment, the color filter layer CF may be omitted. In this case, the light emitting element LD may include patterned red, green, and blue light emitting layers. For example, when the display device DD is the microdisplay, the plurality of sub-pixels SPX may be formed by patterning a color filter material. Accordingly, a fine metal mask (FMM) process may be omitted. However, the disclosure is not limited thereto. For example, the plurality of sub-pixels SPX may be formed in various ways.

In an embodiment, a light emitted from the light emitting element LD might not be recognized by the user when the light is out of the predetermined viewing angle range at a front side (e.g., a direction parallel to the normal line of the substrate SUB). The viewing angle range may be greater than about −10 degrees and less than about +10 degrees at the front side. A light LA emitted at an angle within the viewing angle range at the front side may be recognized by the user.

On the other hand, a light LB emitted at an angle out of the viewing angle range at the front side may be cut while passing through a layer disposed on the light emitting element LD (e.g., the color filter layer CF). Accordingly, the light LB emitted at the angle out of the viewing angle range at the front side might not be recognized by the user.

The color filter layer CF may include a first color filter, a second color filter, and a third color filter.

The first color filter may overlap the first sub-pixel region SPX1. The first color filter may transmit the second light from the first light emitted from the light emitting layer EML (e.g., a white light emitted from the light emitting element LD), and may absorb or block the third light and the fourth light from the first light. For example, the first color filter may transmit the blue light from the white light, and may absorb or block the green light and the red light from the white light. However, the disclosure is not limited thereto. For example, the first color filter may partially overlap the first sub-pixel region SPX1 and the second sub-pixel region SPX2.

The second color filter may overlap the second sub-pixel region SPX2. The second color filter may transmit the third light from the first light emitted from the light emitting layer EML, and may absorb or block the second light and the fourth light from the first light. For example, the second color filter may transmit the green light from the white light, and may absorb or block the blue light and the red light from the white light. However, the disclosure is not limited thereto. For example, the second color filter may partially overlap the second sub-pixel region SPX2 and the third sub-pixel region SPX3.

The third color filter may overlap the second sub-pixel region SPX3. The third color filter may transmit the fourth light from the first light emitted from the light emitting layer EML, and may absorb or block the second light and the third light from the first light. For example, the third color filter may transmit the red light from the white light, and may absorb or block the blue light and the green light from the white light. However, the disclosure is not limited thereto. For example, the third color filter may partially overlap the third sub-pixel region SPX3 and a portion of a sub-pixel region adjacent to the third sub-pixel region SPX3.

In an embodiment, a micro-lens array MLA may be disposed on the color filter layer CF.

In another embodiment, when the color filter layer CF is omitted, the micro-lens array MLA may be disposed on the light emitting element LD. Specifically, the micro-lens array MLA may be disposed on the second electrode CAT.

The micro-lens array MLA may include a plurality of lenses. Each of the lenses included in the micro-lens array MLA may extract, refract, or scatter light. Each of the lenses may have a size of about tens to about hundreds of micrometers, and a refractive index of each of the lenses may be about 1.5 to about 1.7.

In an embodiment, the lenses may overlap the sub-pixel regions SPX1, SPX2, and SPX3, respectively. In another embodiment, the lenses may be disposed in each of the sub-pixel regions SPX1, SPX2, and SPX3.

Alternatively, the micro-lens array MLA may be omitted.

The overcoat layer OC may cover the micro-lens array MLA and may provide a planarized top surface.

In an embodiment, the overcoat layer OC may include or may be formed of an inorganic insulating material. For example, the overcoat layer OC may include or may be formed of silicon oxide (SiO₂), silicon nitride (SiNx), silicon oxynitride (SiON), aluminum oxide (Al₂O₃), titanium dioxide (TiO₂), tantalum pentoxide (Ta₂O₅), hafnium oxide (HfO₂), zirconium dioxide (ZrO₂), or the like. These may be used alone or in combination with each other.

In another embodiment, the overcoat layer OC may include or may be formed of an organic insulating material. For example, the overcoat layer OC may include or may be formed of an acryl-based polymer, an imide-based polymer, an aryl ether-based polymer, an amide-based polymer, a fluorine-based polymer, a p-xylene-based polymer, a vinyl alcohol-based polymer, or the like. These may be used alone or in combination with each other.

In an embodiment, the overcoat layer OC may have a single-layer structure. In another embodiment, the overcoat layer OC may have a multi-layer structure in which an inorganic insulating material layer and an organic insulating material layer are alternately stacked on each other. Alternatively, the overcoat layer OC may have the multi-layer structure in which only layers including materials having high transmittances are stacked in consideration of luminous efficiency.

In an embodiment, the cover window WIN may be disposed on the overcoat layer OC. The cover window WN may protect the display panel.

In an embodiment, the cover window WIN may include or may be formed of glass. The glass may have a flat plate shape. Alternatively, the glass may have a 2D shape in which an edge portion is bent, or a 3D shape in which an overall shape is bent.

In another embodiment, the cover window WIN may include or may be formed of plastic. A display device DD including the plastic may be lighter than a display device including the glass, and stronger against an impact than the display device including the glass.

However, the disclosure is not limited thereto, and the cover window WN may include or may be formed of colorless and optically transparent polyimide (PI), ultra-thin glass, or the like.

In an embodiment, the polarizing layer POL may be disposed on the overcoat layer OC. The polarizing layer POL may reduce external light reflection of the display device DD.

In another embodiment, the polarizing layer POL may be omitted. In this case, the color filter layer CF may reduce the external light reflection. When the polarizing layer POL is omitted from the display device DD, a thickness of the display device DD may be thinned, and light transmittance of the display device DD may be improved.

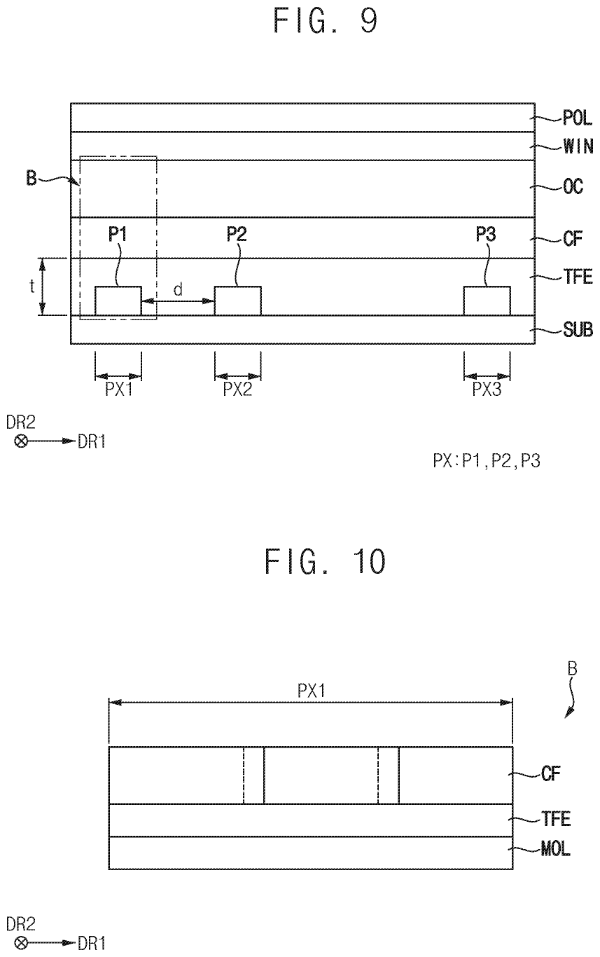

FIG. 6 is a view illustrating an element wiring layer according to an embodiment included in the display device of FIG. 4.

An element wiring layer MOL′ of FIG. 6 may include the first electrode ANO, a light emitting element LD′, the second electrode CAT, and the capping layer CPL. For example, the element wiring layer MOL′ of FIG. 6 may be different from the element wiring layer MOL of FIG. 5 only in stacked layer types and stacked structures of the light emitting elements LD and LD′. Therefore, descriptions will focus on the light emitting element LD′ below.

The light emitting element LD′ may include a light emitting layer EML′ and the functional layer. In an embodiment, the light emitting element LD′ may have the tandem structure. For example, the light emitting element LD′ may include the first hole injection layer HIL1, the first light emitting layer EML1, the first electron transport layer ETL1, the first charge generation layer CGL1, the second hole injection layer HIL2, the second light emitting layer EML2, and the second electron transport layer ETL2. The first hole injection layer HIL1, the first electron transport layer ETL1, the first charge generation layer CGL1, the second hole injection layer HIL2, and the second electron transport layer ETL2 may be sequentially stacked on the substrate SUB. However, the disclosure is not limited thereto. The functional layer may be omitted.

The light emitting element LD′ may include a plurality of light emitting layers EML1 and EML2. For example, the first light emitting layer EML1 may emit the yellow light, and the second light emitting layer EML2 may emit the blue light. Accordingly, the white light may be emitted from the light emitting element LD′. However, the disclosure is not limited thereto. The stacking order or the stacked layer types may be changed.

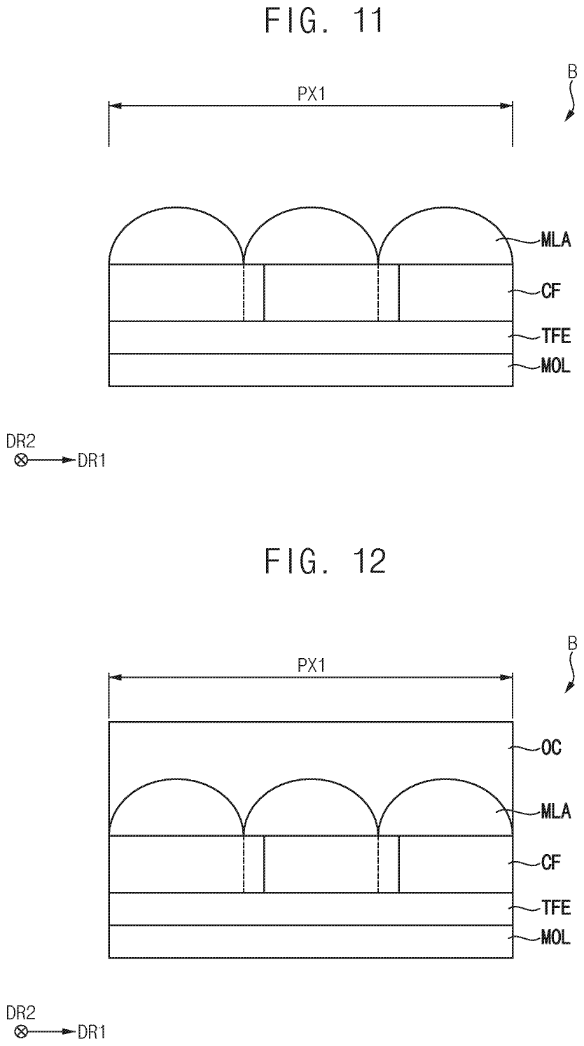

FIGS. 7 to 12 are views illustrating a method of manufacturing a display device according to embodiments of the disclosure. Hereinafter, redundant descriptions corresponding to the display device described above with reference to FIGS. 1, 2, 3, 4, 5, and 6 will be omitted or simplified.

Referring to FIG. 7, the plurality of pixels PX may be formed on the substrate SUB.

Pixels PX may be formed in the first direction DR1 to have the predetermined distance d between the pixels PX. For example, the pixels PX may include a first pixel P1, a second pixel P2, and a third pixel P3. A distance d between the first pixel P1 and the second pixel P2 may be equal to a distance between the second pixel P2 and the third pixel P3.

Although the pixels PX have been shown in FIG. 7 as having the same predetermined distance d, the disclosure is not limited thereto. For example, distances between the pixels PX may be different from each other. In this case, the predetermined distance d may represent the smallest value among the distances between the pixels PX.

In addition, although only the pixels PX have been shown in FIG. 7, each of the pixels PX may include the plurality of sub-pixels (e.g., the sub-pixels SPX of FIG. 3). The minimum distance between the pixels PX may be a first distance. The minimum distance between the sub-pixels may be a second distance. In this case, the predetermined distance d may represent the smallest value among the first distance and the second distance.

Referring to FIGS. 7 and 8, the encapsulation layer TFE may be formed on the substrate SUB. The encapsulation layer TFE may cover the plurality of pixels PX.

The encapsulation layer TFE may be formed to have the predetermined thickness t. In this case, the relation between the distance d between the pixels PX and the thickness t of the encapsulation layer TFE may satisfy Mathematical Formula 1 below. Here, the predetermined thickness t may have the maximum thickness of d/tan(10º) for the distance d. For example, when the encapsulation layer TFE has the single-layer structure, the predetermined thickness t may have the maximum thickness of the single layer. On the other hand, when the encapsulation layer TFE has the multi-layer structure, the predetermined thickness t may have the largest value of)d/tan(10° among sum of the thicknesses of the plurality of layers.

$$t \leq \frac{d}{tan 10 °} \qquad 〈 Mathematical Formula 1 〉$$

As shown in Mathematical Formula 1, the thickness of the encapsulation TFE may be smaller than the value obtained by dividing the minimum distance between the plurality of pixels PX by about tan 10°. Alternatively, the maximum thickness of the encapsulation TFE may be formed to have the same thickness as a value obtained by dividing the minimum distance between the plurality of pixels PX by about tan 10°.

Referring to FIGS. 8 and 9, the color filter layer CF may be formed on the encapsulation layer TFE.

The color filter layer CF may include the first color filter, the second color filter, and the third color filter. For example, the first color filter may be formed to overlap the first sub-pixel region SPX1 and the second sub-pixel region SPX2. The second color filter may be formed to overlap the second sub-pixel region SPX2 and the third sub-pixel region SPX3. The third color filter may be formed to overlap the third sub-pixel region SPX3 and the sub-pixel region adjacent to the third sub-pixel region SPX3. However, the disclosure is not limited thereto, the number, an arrangement, or the like of color filters included in the color filter layer CF may be variously changed, and the color filter layer CF may be omitted.

The overcoat layer OC, the cover window WIN, and the polarizing layer POL may be formed on the color filter layer CF. Accordingly, the display device (e.g., the display device DD of FIG. 1) may be formed.

Referring to FIGS. 10, 11, and 12, the method for manufacturing the display device may further include forming the micro-lens array MLA after forming the color filter layer CF and before forming the overcoat layer OC.

In an embodiment, the micro-lens array MLA may be formed on the color filter layer CF. The micro-lens array MLA may be formed to include the plurality of lenses. For example, the micro-lens array MLA may include a first lens, a second lens, and a third lens. The first lens, the second lens, and the third lens may be formed to overlap a first pixel region PX1. However, the present disclosure is not limited thereto, and the number, an arrangement, and the like of the lenses included in the micro-lens array MLA may be variously changed.

In another embodiment, when the color filter layer CF is omitted, the micro-lens array MLA may be formed on the encapsulation layer TFE. Specifically, as described above with reference to FIGS. 1, 2, 3, 4, 5, and 6, the micro-lens array MLA may be formed on the second electrode (e.g., the second electrode CAT of FIG. 5). Alternatively, a process of forming the micro-lens array MLA may be omitted.

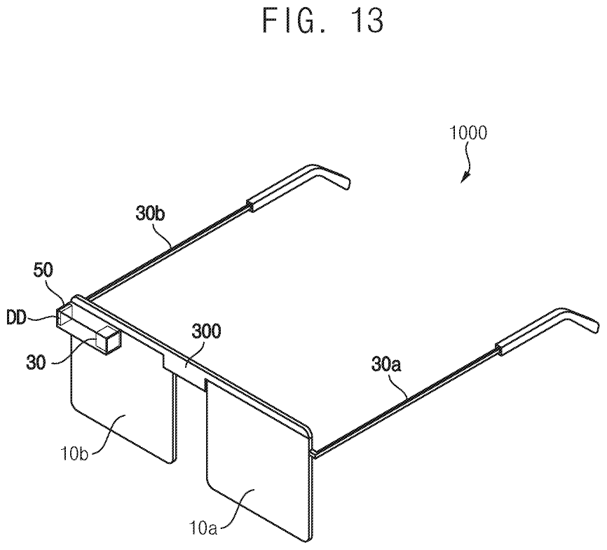

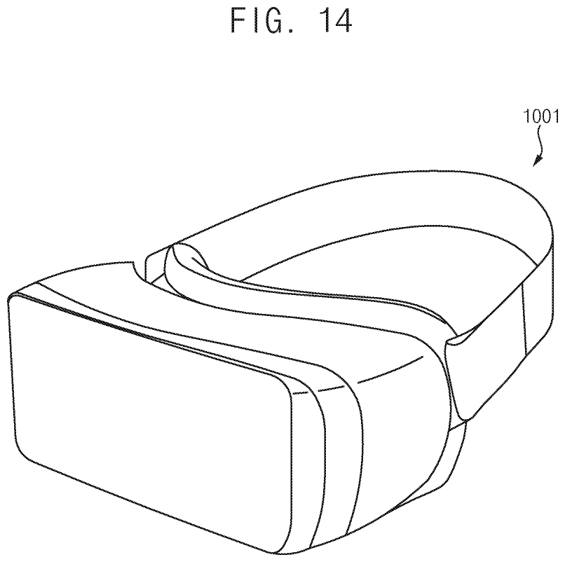

FIG. 13 is view illustrating an embodiment in which the display device of FIG. 1 is implemented as smart glasses. FIG. 14 is a view illustrating an embodiment in which the display device of FIG. 1 is implemented as a head mounted display device.

Referring to FIGS. 13 and 14, the display device DD may be implemented as virtual reality devices 1000 and 1001. For example, the virtual reality device 1000 of FIG. 13 may be smart glasses, and the virtual reality device 1001 of FIG. 14 may be a head mounted display (HMD).

In an embodiment, the virtual reality device 1000 may include the display device DD, a plurality of lenses 10a and 10b, support frames 30a, 30b and 300, and a housing 50. A reflector 30 and the display device DD may be disposed in the housing 50. The image provided by the display device DD may be reflected by the reflector 30, and the image reflected by the reflector 30 may be provided to both eyes of the user.

The housing 50 may be located outside the virtual reality device 1000. In FIG. 13, it is shown that the housing 50 is disposed adjacent to one of temples, however, the disclosure is not limited thereto. For example, the housing 50 may be located in a center of the virtual reality device 1000.

In another embodiment, the virtual reality device 1001 might not include the temples 30a, 30b of the support frames 30a, 30b, and 300. In this case, the virtual reality device 1001 may further include a head-mounted band.

However, the display device according to embodiments of the disclosure is not limited thereto. For example, the display device according to embodiments of the disclosure may be implemented for a smart watch, a smart accessory such as a smart ring, a mobile phone, a video phone, a smart pad, a tablet PC, a car navigation system, a television, a laptop computer, or the like.

The display device according to the embodiments may be applied to a display device included in a computer, a laptop, a smart phone, a VR device, an AR device, or the like.

Although certain embodiments and implementations have been described herein, other embodiments and modifications will be apparent from this description. Accordingly, the inventive concepts are not necessarily limited to the embodiments described herein, but rather various modifications and equivalent arrangements as would be apparent to a person of ordinary skill in the art are within the scope of the disclosure.

What is claimed is:

1. A display device comprising:
a substrate;
a plurality of pixels disposed on the substrate; and
an encapsulation layer disposed on the plurality of pixels, and having a single-layer structure,
wherein a distance (d) between the plurality of pixels and a thickness (t) of the encapsulation layer are configured to satisfy the relation of t≤ (d/tan 10°).

2. The display device of claim 1,
wherein the substrate includes a silicon substrate.

3. The display device of claim 1,
wherein each of the plurality of pixels includes:
a first electrode disposed on the substrate;
a light emitting element disposed on the first electrode; and
a second electrode disposed on the light emitting element.

4. The display device of claim 3,
wherein the light emitting element includes a plurality of light emitting layers.

5. The display device of claim 3,
wherein the light emitting element is configured to emit a white light.

6. The display device of claim 5, further comprising a color filter layer disposed on the encapsulation layer.

7. The display device of claim 3, further comprising a plurality of lenses disposed on the second electrode.

8. The display device of claim 7,
wherein each of the plurality of pixels includes a plurality of sub-pixels, and
wherein the plurality of lenses overlap the plurality of sub-pixels, respectively.

9. The display device of claim 3,
wherein the first electrode is an anode and the second electrode is a cathode.

10. The display device of claim 1,
wherein the distance (d) has a value of a micrometer scale or less.

11. A display device comprising:
a substrate;
a plurality of pixels disposed on the substrate; and
an encapsulation layer disposed on the plurality of pixels, and having a multi-layer structure,
wherein a distance (d) between the plurality of pixels and a thickness (t) of the encapsulation layer are configured to satisfy the relation of t≤ (d/tan 10°).

12. The display device of claim 11,
wherein the substrate includes a silicon substrate.

13. The display device of claim 11,
wherein each of the plurality of pixels includes:
a first electrode disposed on the substrate;
a light emitting element disposed on the first electrode; and
a second electrode disposed on the light emitting element.

14. The display device of claim 13,
wherein the light emitting element includes a plurality of light emitting layers.

15. The display device of claim 13,
wherein the light emitting element is configured to emit a white light.

16. The display device of claim 15, further comprising a color filter layer disposed on the encapsulation layer.

17. The display device of claim 13, further comprising a plurality of lenses disposed on the second electrode.

18. The display device of claim 17,
wherein each of the plurality of pixels includes a plurality of sub-pixels, and
wherein the plurality of lenses overlap the plurality of sub-pixels, respectively.

19. The display device of claim 13,
wherein the first electrode is an anode and the second electrode is a cathode.

20. The display device of claim 11,
wherein the distance (d) has a value of a micrometer scale or less.

21. A display device comprising:
a substrate;
a plurality of pixels disposed on the substrate and spaced apart from each other at a first distance (d1), wherein each of the plurality of pixels includes a plurality of sub-pixels that are spaced apart from each other at a second distance (d2); and
an encapsulation layer disposed on the plurality of pixels and having a thickness (t),
wherein the thickness (t) and a smaller distance (d) of the first distance (d1) and the second distance (d2) are configured to satisfy the relation of t≤ (d/tan 10°).

22. The display device of claim 21,
wherein the substrate includes a silicon substrate.

23. The display device of claim 21,
wherein each of the plurality of pixels includes:
a first electrode disposed on the substrate;
a light emitting element disposed on the first electrode; and
a second electrode disposed on the light emitting element.

24. The display device of claim 23, further comprising a plurality of lenses disposed on the second electrode.

25. The display device of claim 24,
wherein each of the plurality of pixels includes a plurality of sub-pixels, and
wherein the plurality of lenses overlap the plurality of sub-pixels, respectively.

26. The display device of claim 21,
wherein the distance (d) has a value of a micrometer scale or less.
